(19) United States
(12) Patent Application Publication
(10) Pub. No.: US 2023/0086417 A1
(43) Pub. Date: Mar. 23, 2023

(54) COMPOSITION FOR TREATING SEMICONDUCTOR SUBSTRATE

(71) Applicant: ENF TECHNOLOGY CO., LTD., Gyeonggi-do (KR)

(72) Inventors: Jeong Sik OH, Gyeonggi-do (KR); Tae Ho KIM, Gyeonggi-do (KR); Gi Young KIM, Gyeonggi-do (KR); Myung Ho LEE, Gyeonggi-do (KR); Myung Geun SONG, Gyeonggi-do (KR)

(21) Appl. No.: 17/871,094

(22) Filed: Jul. 22, 2022

(30) Foreign Application Priority Data
Jul. 23, 2021 (KR) 10-2021-0097192

(51) Int. Cl. C11D 1/00; C11D 11/00; C11D 3/43; C11D 3/18

(52) U.S. Cl. CPC C11D 1/004; C11D 11/0047; C11D 3/43; C11D 3/187; H01L 21/02087

(57) ABSTRACT

The present invention relates to a composition for treating a semiconductor substrate, and particularly to a composition for treating an edge portion of a wafer coated with polysilazane.

According to the composition for treating a semiconductor substrate according to the present invention, it is possible to uniformly maintain the quality of the composition in terms of management and to uniformly treat the boundary of the wafer in terms of processing. In addition, by improving the straightness of the boundary portion where polysilazane is removed, it is possible to significantly reduce the defect rate of the product and to stably improve the productivity yield.

### CROSS REFERENCE TO RELATED APPLICATIONS

This application claims the benefits of priority to Korean Patent Application No. 10-2021-0097192, filed Jul. 23, 2021, incorporated herein by reference.

### TECHNICAL FIELD

The present invention relates to a composition for treating a semiconductor substrate, and particularly to a composition for treating an edge portion of a wafer coated with polysilazane.

### BACKGROUND ART

Conventionally, in a semiconductor manufacturing process, a silica film has been formed by a physical vapor deposition method (PVD, sputtering method), a chemical vapor deposition (CVD), or a sol-gel method or through forming a polysiloxane or polysilazane film. Of these, the method of forming a polysiloxane or polysilazane film and converting into a silica film can provide an excellent silica film by low-temperature sintering. The silica film is used for an insulating film, a planarization film, a passivation film, etc. of a semiconductor element in a liquid crystal display device or the like.

The silica film is generally formed by a method comprising spin coating a polysilazane solution on a substrate, heating it to remove a solvent, and sintering it to convert the polysilazane film into a silica film. In the step of spin coating the polysilazane solution on the substrate, the solution is spread to coat on the back surface of the substrate while beads are formed on the edge of the substrate. At this time, an edge bead removal (EBR) or edge rinse process is generally performed in order to prevent the non-uniform thickness of the coating film from forming along the periphery of the substrate due to beads and a back rinse process is performed to remove polysilazane attached to the back surface of the surface.

As described above, in the process of applying the polysilazane film on the substrate, peeling or removing of unnecessary polysilazane from the substrate or the coating device may be required. The composition to be used is known, for example, a co-solvent mixture such as propylene glycol monomethyl ether acetate (PGMEA).

However, according to such a composition, since it is difficult to sufficiently peel or remove polysilazane, a hump height of the film thickness is likely to occur at the boundary where polysilazane is removed. This hump height of the film thickness may cause cracks or peeling during sintering of the film, so that there is a risk that the product may have defects. In addition, since there is a risk of clogging of the coating device due to gelation of waste liquid generated during the process, it is necessary to frequently perform operations for preventing clogging in the device during the process. Moreover, gases such as silane, hydrogen, ammonia, etc. are generated in the waste tank exceeding spontaneous ignition limits thereof, affecting the stability.

Therefore, there is a need for a composition for treating a semiconductor substrate having excellent solubility in polysilazane that need to be removed and improved straightness of the boundary portion where polysilazane is removed.

### DETAILED DESCRIPTION OF THE INVENTION

### Technical Problem

It is an object of the present invention to provide a composition for effectively treating a semiconductor substrate coated with polysilazane.

### Solution to Problem

In order to solve the above problems, the present invention provides a composition for treating a semiconductor substrate, comprising, based on the total weight of the composition, 98 to 99.8% by weight of trimethylbenzene; and a fluorine-based surfactant.

According to one embodiment, the fluorine-based surfactant molecule may be linear or branched.

For example, the fluorine-based surfactant may comprise at least one of compounds represented by formulas 1 to 4.

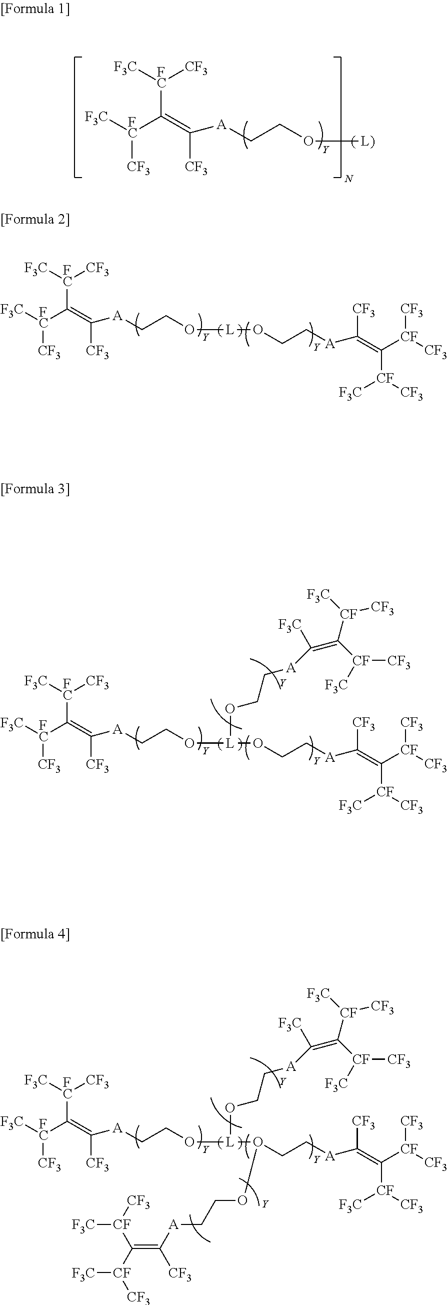

In formulas 1 to 4,

A is O, NR, ethylene oxide, (C₁₋₁₀) alkyl or SR, wherein R is a (C₁₋₁₀) alkyl group,

Y is an integer from 1 to 10,

N is an integer from 1 to 4, and

L is H, C, (C₁₋₂) alkoxy (C₁₋₂) alkanol or (C₁₋₂) alkanol.

Specifically, the fluorine-based surfactant is at least one compound of compounds represented by formulas 5 to 8, for example.

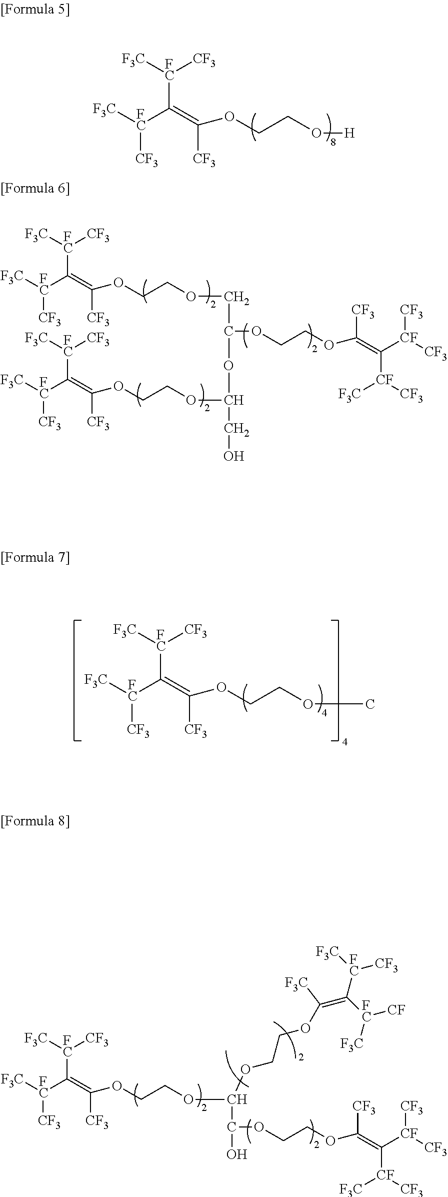

According to one embodiment, the composition of the present invention may contain 0.001 to 0.3% by weight of the fluorine-based surfactant based on the total weight of the composition.

According to another embodiment of the present invention, there is provided a method for treating a semiconductor substrate with the composition as described above.

The specific details of other embodiments according to the invention are included in the detailed description below.

### Effect of the Invention

According to the composition for treating a semiconductor substrate according to the present invention, it is possible to uniformly maintain the quality of the composition in terms of management and to uniformly treat the boundary of the wafer in terms of processing. In addition, by improving the straightness of the boundary portion where polysilazane is removed, it is possible to significantly reduce the defect rate of the product and to stably improve the productivity yield.

### BRIEF DESCRIPTION OF DRAWINGS

FIG. 1 is a photograph showing the result of observing the state of the EBR boundary.

### MODE FOR CARRYING OUT THE INVENTION

The present invention may have various modification and various embodiments and specific embodiments will be illustrated in the drawings and described in detail. However, this is not intended to limit the present invention to specific embodiments, and should be understood to include all modifications, equivalents, and substitutes included in the spirit and scope of the present invention. In describing the present invention, if it is determined that a detailed description of a related known technology may obscure the gist of the present invention, the detailed description thereof will be omitted.

Unless otherwise specified, the expression “to” in relation to a number used herein is used as an expression including the corresponding numerical value. Specifically, for example, the expression “1 to 2” is meant to include all numbers between 1 and 2 as well as 1 and 2.

A wafer coated with polysilazane is generally applied to a semiconductor substrate. In the polysilazane coating process, heads are formed at the edge of the wafer. The polysilazane beads are removed to improve production efficiency. Conventionally, there is a problem that a film thickness at the boundary is increased (hump height) after edge bead removal (EBR).

An object of the present invention is to improve the straightness of the boundary portion where polysilazane is removed by providing a composition for treating a semiconductor substrate comprising a single solvent or a very small amount of additive.

Hereinafter, the composition for treating a semiconductor substrate according to an embodiment of the present invention will be described in more detail.

The composition of the present invention comprises high-purity trimethylbenzene in a high content. For example, the composition may contain 98 to 99.8% by weight of trimethylbenzene, for example, 99% by weight or more, 99.1% by weight or more, 99.2% by weight or more, and for example, 99.8% by weight or less, 99.5% by weight or less based on the total weight of the composition of the present invention.

When a low-purity solvent mixture is used, the type and content of impurities tend to increase, making it difficult to maintain uniform quality. On the other hand, in the present invention, the quality of the composition can be uniformly maintained by including high-purity trimethylbenzene in a high content. In addition, it is possible to prevent problems in edge head removal performance during or after the siloxane or silazane film removal process.

In addition, the present invention further comprises a small amount of a fluorine-based surfactant. The fluorine-based surfactant serves to inhibit the penetration of the composition into the polysilazane layer in the initial stage of dissolution of the polysilazane. Thereafter, the fluorine-based surfactant is partly arranged at the boundary where the dissolution reaction proceeds.

It results in prevention penetration into the polysilazane coating layer of the composition for treating a semiconductor substrate, thereby reducing a thickness hump and improving the straightness of the boundary.

The fluorine-based surfactant may include fluorine-based surfactants having a linear or branched molecular structure. In the reaction between the composition and polysilazane, the branched fluorine-based surfactant serves to capture moisture. Aggregation of polysilazane can be prevented by controlling the reactivity of polysilazane and water and thus process efficiency can be improved.

For example, the fluorine-based surfactant may comprise at least one compound of compounds represented by Formulas 1 to 4.

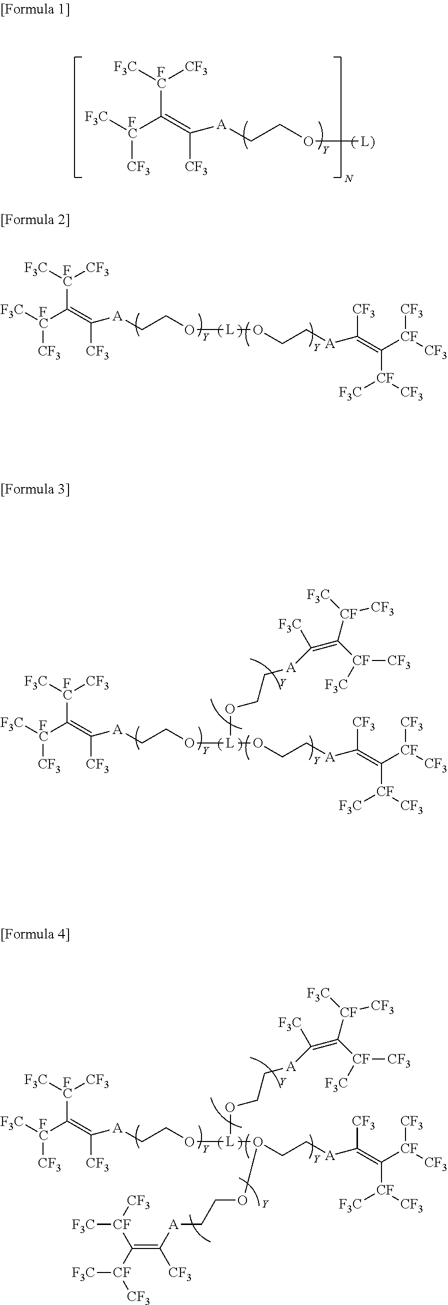

In formulas 1 to 4,

A is O, NR, ethylene oxide, (C₁₋₁₀) alkyl or SR, wherein R is a (C₁₋₁₀) alkyl group,

Y is an integer from 1 to 10,

N is an integer from 1 to 4, and

L is H, C, (C₁₋₂) alkoxy (C₁₋₂) alkanol or (C₁₋₂) alkanol.

Specifically, the fluorine-based surfactant is at least one compound of compounds represented by formulas 5 to 8, for example.

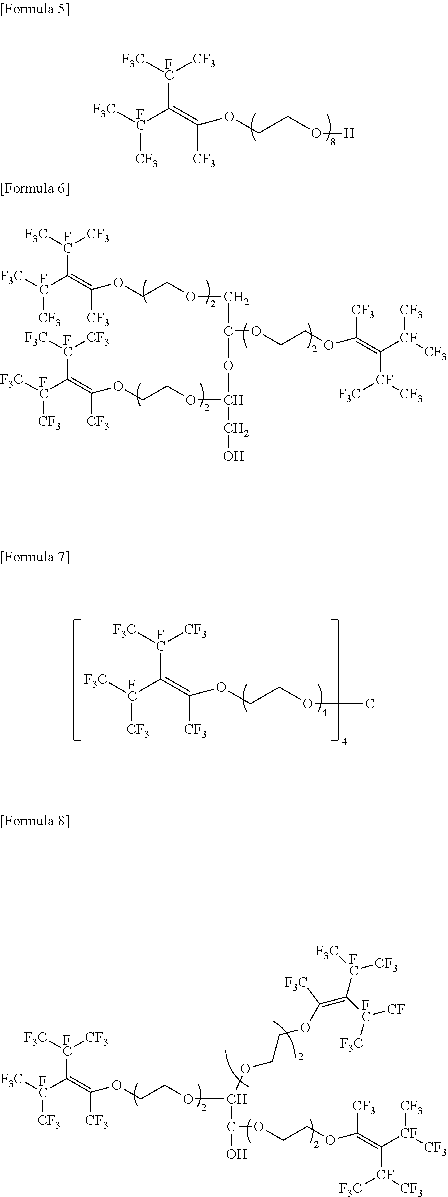

According to one embodiment, the composition may contain the fluorine-based surfactant in an amount of 0.001 to 0.3% by weight, for example, 0.001% by weight or more, 0.005% by weight or more or 0.01% by weight or more, and for example, 0.3% by weight or less, 0.2% by weight % or less, 0.1 wt % or less, 0.05 wt % or less or 0.03 wt % or less, based on the total weight of the composition.

According to another embodiment of the present invention, there is provided a method for treating a semiconductor substrate as described above.

According to the present invention, a hump height phenomenon can be prevented during edge bead removal (EBR) of the polysilazane coating layer from the wafer, and the straightness of the polysilazane boundary can be improved.

Hereinafter, embodiments of the present invention will be described in detail so that those of ordinary skill in the art can easily carry out the present invention. However, the present invention may be embodied in several different forms and is not limited to the embodiments described herein.

### EXAMPLES AND COMPARATIVE EXAMPLES

A composition for treating a semiconductor substrate was prepared with the composition according to Table 1. The composition contains water in the amount sufficient to make the said composition 100% by weight.

TABLE 1

| | Solvent (wt %) | | Fluorine-based surfactant (ppm) | |
|---|---|---|---|---|
| Comparative | C8-C11 aromatic | 99 | | |
| Example 1 | hydrocarbon | | | |
| | mixture | | | |
| Comparative | TMB | 99 | | |
| Example 2 | | | | |
| Example 1 | TMB | 99 | Formula 5 | 100 |
| Example 2 | TMB | 99 | Formula 5 | 300 |
| Example 3 | TMB | 99 | Formula 6 | 100 |
| Example 4 | TMB | 99 | Formula 6 | 300 |
| Example 5 | TMB | 99 | Formula 8 | 100 |
| Example 6 | TMB | 99 | Formula 8 | 300 |
| Example 7 | TMB | 99 | Formula 7 | 100 |
| Example 8 | TMB | 99 | Formula 7 | 300 |

### Experimental Example 1: Edge Bead Removal (EBR)

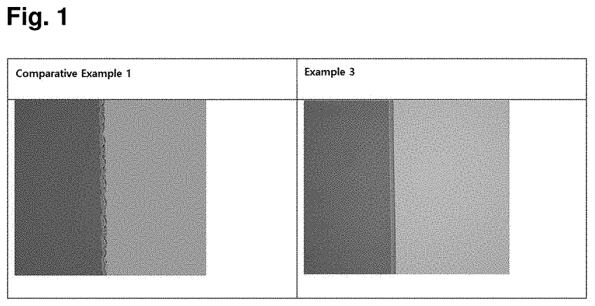

After EBR with each composition on the polysilazane-coated semiconductor wafer substrate, the state of the boundary where polysilazarte was removed was observed. In FIG. 1, the left side is a photograph observing the boundary according to Comparative Example 1, and the right side corresponds to Example 3.

### Experimental Example 2: Stability Analysis

In order to confirm stability of the composition, a sample aged after mixing with polysilazane was analyzed with a turbidimeter (HACH).

### Experimental Example 3: Bubble Generation

During the EBR process, the presence or absence of bubbles in the composition was observed. When bubbles were generated, “0” was indicated, and when no bubbles were generated, “X” was indicated.

Table 2 shows the results according to the experimental example.

TABLE 2

| | | | Stability (Turbidity | |
|---|---|---|---|---|
| | | | analysis @ 1 day) | |
| | EBR boundary (Å) | | (Aggregation of | |
| | | Boundary | polysilazane) | Bubble |
| | Height | width (Tail) | (NTU) | generation |
| Comparative | 1470 | >70 | 8.4 | X |
| Example 1 | | | | |
| Comparative | 1580 | >72 | 8.1 | X |
| Example 2 | | | | |
| Example 1 | 1120 | <58 | 5.2 | X |
| Example 2 | 1020 | <42 | 4.7 | ◯ |
| Example 3 | 980 | <35 | 5.1 | X |
| Example 4 | 920 | <31 | 4.6 | ◯ |
| Example 5 | 1050 | <64 | 3.2 | X |
| Example 6 | 1010 | <59 | 3.0 | ◯ |
| Example 7 | 890 | <37 | 3.5 | X |
| Example 8 | 870 | <33 | 2.1 | ◯ |

As shown in Table 2, it was confirmed that the compositions of Comparative Examples result in a wide width of the EBR boundary and high aggregation of polysilazane, and thus the lowered stability, so that they are not suitable as the composition for treating a semiconductor substrate.

On the other hand, it was confirmed that all of Examples have good state of the EBR boundary and excellent stability. In particular, in the case of Examples 1 to 8 in which the fluorine-based surfactant was added, it was confirmed that the stability and EBR boundary were excellent compared to Comparative Examples 1 and 2 in which only a single solvent is used.

As described above, the composition for treating a semiconductor substrate according to the present invention can minimize the occurrence of bubbles and maintain the stability of the composition when used in the EBR process. In addition, it was confirmed that the straightness was greatly improved because the EBR boundary could be treated uniformly.

As described above, specific parts of the present invention have been described in detail, and it is clear that these specific descriptions are only preferred embodiments for those of ordinary skill in the art to which the present invention pertains, and the scope of the present invention is not limited thereto. Those of ordinary skill in the art to which the present invention pertains will be able to make various applications and modifications within the scope of the present invention based on the above contents. Accordingly, the substantial scope of the present invention will be defined by the appended claims and their equivalents.

What is claimed is:

1. A composition for treating a semiconductor substrate, comprising,
based on the total weight of the composition,
98 to 99.8% by weight of trimethylbenzene; and
a fluorine-based surfactant.

2. The composition for treating a semiconductor substrate according to claim 1,
wherein the fluorine-based surfactant molecule is linear or branched.

3. The composition for treating a semiconductor substrate according to claim 1,
wherein the fluorine-based surfactant comprises at least one compound of compounds represented by formulas 1 to 4: 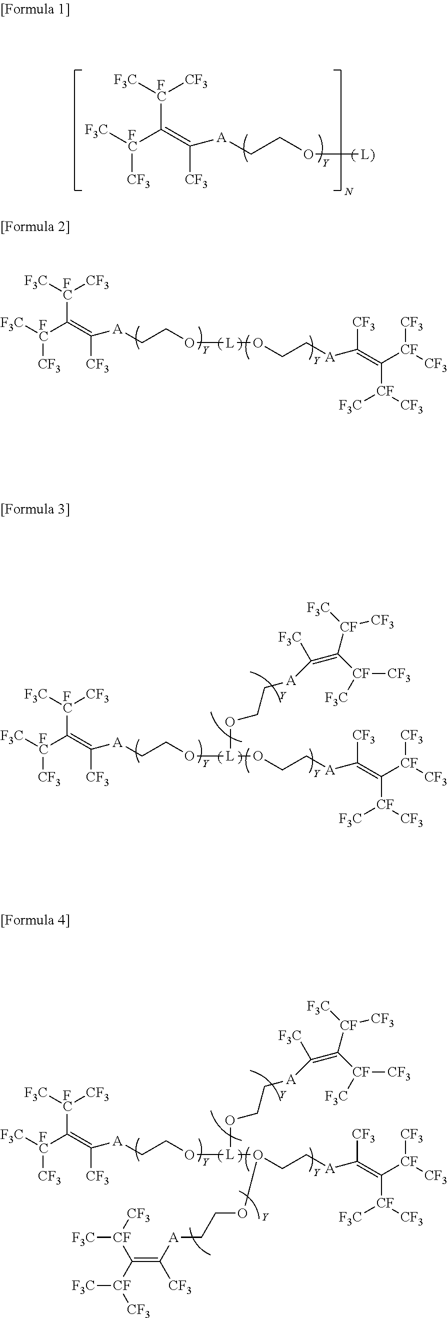
In formulas 1 to 4,
A is O, NR, ethylene oxide, (C₁₋₁₀) alkyl or SR, wherein R is a (C₁₋₁₀) alkyl group,
Y is an integer from 1 to 10,
N is an integer from 1 to 4, and
L is H, C, (C₁₋₂) alkoxy (C₁₋₂) alkanol or (C₁₋₂) alkanol.

4. The composition for treating a semiconductor substrate according to claim 1, wherein the fluorine-based surfactant is at least one compound of compounds represented by formulas 5 to 8:

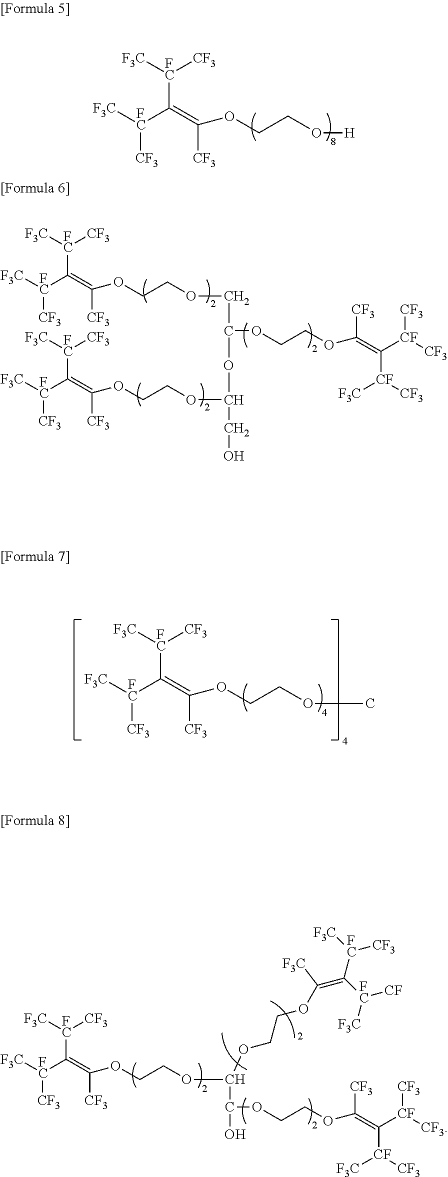

5. The composition for treating a semiconductor substrate according to claim 1, wherein the composition contains 0.001 to 0.3% by weight of the fluorine-based surfactant based on the total weight of the composition.

6. A method for treating a semiconductor substrate with the composition of claim 1.
